(19) United States
(12) Patent Application Publication
(10) Pub. No.: US 2008/0251116 A1
(43) Pub. Date: Oct. 16, 2008

(54) Artificial Amorphous Semiconductors and Applications to Solar Cells

(76) Inventor: Martin Andrew Green, New South Wales (AU)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 11/579,105

(22) PCT Filed: Apr. 29, 2005
(86) PCT No.: PCT/AU05/00614

§ 371 Date: Jan. 24, 2008

(30) Foreign Application Priority Data
Apr. 30, 2004 (AU) 2004902299

(51) Int. Cl. H01L 31/0376; H01L 21/20; H01L 29/04; H01L 31/18

(52) U.S. Cl. 136/255; 438/482; 438/96; 257/21; 257/E31.049; 257/E31.048; 257/E29.003; 257/E21.09

(57) ABSTRACT

An artificial amorphous semiconductor material, and a junction made from the material, has a plurality of crystalline semiconductor material quantum dots substantially uniformly distributed and regularly spaced in three dimensions through a matrix of dielectric material or thin layers of dielectric materials. The material is formed by first forming a plurality of layers of dielectric material comprising a compound of a semiconducting material, and forming alternating layers as layers of stoichiometric dielectric material and layers of semiconductor rich dielectric material respectively. The material is then heated causing quantum dots to form in the semiconductor rich layers of dielectric material in a uniform and regularly spaced distribution in three dimensions through the dielectric material. The bandgap and mobility of the material are determined by selecting the material parameters including the size of the quantum dots, the composition of the matrix and the semiconductor material of the quantum dots to achieve the desired parameters.

### CROSS-REFERENCE TO RELATED APPLICATIONS

The present application claims priority from Australian Provisional Patent Application No 2004902299 filed on 30 Apr. 2004, the content of which is incorporated herein by reference.

### INTRODUCTION

The present invention relates generally to the field of photovoltaics and in particular the invention provides a new class of materials and methods for forming thin-film solar cells using those materials.

### BACKGROUND

Conversion of sunlight to electricity using solar cells is one of the most appealing ways yet suggested for generating the world's future energy supplies.

Solar cells are presently based on wafers of the semiconductor silicon, similar to those used in microelectronics. The cost of these wafers accounts for a large fraction of the total cost of the final solar module, limiting the potential for low-cost, large scale electricity generation by this approach.

Several “thin-film” solar cell approaches are under development to avoid these wafer costs by depositing thin layers of semiconductor onto a supporting substrate or superstrate, usually glass. Although offering lower cost potential, commercialisation of these technologies has been slow since the materials that have been the focus of such efforts (amorphous silicon/hydrogen alloys, copper indium diselenide and cadmium telluride) have been unstable, moisture sensitive, involve toxic material or materials in limited supply, or have demonstrated a combination of these deficiencies.

Recently, technology has been reported based on depositing, onto glass, thin layers of crystalline silicon, of the same type and general quality as used in the well proven wafer technology. A characteristic of this technology is its excellent stability and durability since it uses only silicon, although energy conversion efficiency to date has been modest (8-9% compared to 10-15% for commercial wafer-based modules).

One way of extending the performance of thin-film solar cells is by the tandem cell concept where cells of increasing bandgap are stacked on top of one another. In this way, each cell converts only a narrow band of wavelengths within the solar spectrum allowing higher overall efficiency. Ideally, stacking 2 cells improves performance by 40% relative, while stacking 3 cells improves performance by 60% relative However, finding suitable material to stack on top of a crystalline silicon cell is problematic.

### Superlattices

The effect of quantum confinement obtained by limiting at least one spatial dimension of material samples has been understood since at least the 1960s and super lattices have been known since 1970. As first conceived, quantum wells of semiconductor material of low bandgap material are separated by semiconducting barrier regions of a higher bandgap with a regular spacing of the quantum wells and a regular width of each well (FIG. 1). Such devices were manufacturable with the epitaxial growth techniques available to III-V compound semiconductor technology at that time. Although their preparation has been more problematic, the concept of regular quantum dot superlattices soon emerged.

As shown schematically in FIG. 1, in quantum dot and quantum well superlattices 11, the energy available to a carrier in a quantum dot or well spreads into a band of available energies 12, 13, 14, 15, 16 as the extent of the barrier region between wells decreases. Electron conduction within these “mini-bands” then becomes possible. The effective bandgap of the resulting material is controlled primarily by the size of the quantum dot or quantum well and the width of the mini-bands and the carrier mobility within these are controlled by the distance between wells.

### Silicon Quantum Dots

Several techniques have been demonstrated for the fabrication of silicon quantum dots. Perhaps the most popular is ion implantation of silicon into thermally grown silicon oxides. Subsequent heating causes the excess silicon introduced into the oxide to precipitate out as quantum dots of various sizes. Another technique is the direct preparation of non-stoichiometric silicon dioxide by sputtering or reactive evaporation. Layers containing silicon nanocrystals in an amorphous matrix separated by layers of insulating SiO₂ have been prepared by reactive magnetron sputtering using hydrogen reduction to prepare the silicon-rich regions. A related technique is the evaporation of SiOₓ/SiO₂ amorphous layer superlattices with x≈1, with silicon quantum dots subsequently precipitated out at high temperatures largely within the SiOₓ layers.

### SUMMARY OF THE INVENTION

According to a first aspect, the present invention consists in a an artificial amorphous semiconductor material having a controlled bandgap and mobility comprising a plurality of crystalline semiconductor material quantum dots substantially uniformly distributed and regularly spaced in three dimensions through a matrix of dielectric material or thin layers of dielectric materials wherein the bandgap and mobility of the material are determined by selecting the material parameters including the size of the quantum dots, the composition of the matrix and the semiconductor material of the quantum dots.

According to a second aspect of the invention a method of forming an artificial amorphous semiconductor material having a controlled bandgap and mobility comprises;

forming a plurality of layers of dielectric material comprising a compound of a semiconducting material, wherein alternating layers are layers of stoichiometric dielectric material and layers of semiconductor rich dielectric material respectively, and

heating the layers of dielectric material to cause quantum dots to form in the semiconductor rich layers of dielectric material whereby they are uniformly distributed and regularly spaced in three dimensions through the dielectric material,

wherein the bandgap and mobility are determined by selecting the material parameters including the size of the quantum dots, the composition of the matrix and the semiconductor material of the quantum dots to achieve the desired parameters.

According to a third aspect, the present invention consists in a photovoltaic junction comprising an n-type region of artificial amorphous material adjacent a p-type region of artificial amorphous material forming a junction there between, the n-type and p-type artificial amorphous materials being integrally formed as a matrix of dielectric material in which is substantially regularly disbursed a plurality of crystalline semiconductor material quantum dots and wherein the n-type and p-type regions are respectively doped with n-type and p-type dopant atoms.

According to a fourth aspect of the invention a method of forming an artificial amorphous semiconductor material photo voltaic cell comprises;

forming a plurality of layers of dielectric material comprising a compound of a semiconducting material, wherein alternating layers are layers of stoichiometric dielectric material and layers of semiconductor rich dielectric material respectively,

doping regions of the plurality of layers of dielectric material with p-type and n-type dopants either simultaneously with their formation or subsequently, and

heating the layers of dielectric material to cause quantum dots to form in the semiconductor rich layers,

wherein the bandgap and mobility are determined by selecting the material parameters including the size of the quantum dots, the composition of the matrix and the semiconductor material of the quantum dots to achieve the desired parameters.

A region in the vicinity of the junction between the n-type and p-type regions of the artificial amorphous material may be undoped or have a balance of n-type and p-type dopants whereby the region behaves as intrinsic material.

The quantum dots are distributed in layers throughout the artificial amorphous material and each of the n-type and p-type regions will typically include 20-50 layers of quantum dots and preferably about 25 layers formed by providing that number of each of the alternating stoichiometric and semiconductor rich layers. The n-type and p-type regions are typically each in the range of 75-200 nm thick and preferably about 100 nm thick. This is achieved by creating each layer of dielectric material with a thickness in the range of 1.5 to 2.5 nm and preferably about 1.9 to 2.1 nm and providing 25 of each of the stoichiometric and semiconductor rich layers (i.e. 50 layers in all) in each of the doped regions to give a cell having a thickness of 150 to 250 and preferably 200 nm thick.

The dielectric material is preferably silicon oxide, silicon nitride or silicon carbide or a structure including layers of one or more of these materials possibly with layers of other materials included. The semiconductor material of the quantum dots is preferably silicon or a silicon alloy such as silicon alloyed with germanium.

Artificial amorphous material photovoltaic cells may be stacked in tandem with other artificial amorphous material photovoltaic cells and/or cells of more conventional material such as poly crystalline silicon cells. When a plurality of cells are stacked in tandem the bandgaps of the artificial amorphous material cells are preferably varied from cell to cell (and with respect to any base line silicon cell) whereby each cell is optimised for a different wavelength of incident light on the tandem structure. Conventional material may also be used adjacent to an artificial amorphous material layer to assist in connecting to the artificial amorphous material.

### BRIEF DESCRIPTION OF THE DRAWINGS

Embodiments of the invention will now be described with reference to the accompanying drawings in which:

FIG. 1 shows an energy diagram for a Superlattice showing minibands;

FIG. 2 diagrammatically illustrates a superlattice structure formed by deposition of alternating stoichiometric and silicon-rich layers;

FIG. 3 shows the layers of FIG. 2 after high temperature treatment showing crystalline silicon quantum dots;

FIGS. 4(a), 4(b) and 4(c) illustrate bulk band alignments between crystalline silicon and its carbide, nitride and oxide (estimated) respectively;

FIG. 5 diagrammatically illustrates Quantum dot parameters;

FIG. 6 diagrammatically illustrates a Quantum dot array formed on a textured surface (not to scale);

FIG. 7 diagrammatically illustrates a generic tandem cell design based on superlattices of quantum dot material;

FIG. 8 is an energy diagram of a tunneling junction connection in a III-V crystalline device;

FIG. 9 is an energy diagram of a tunneling junction based on lower bandgap baseline material; and

FIG. 10 diagrammatically illustrates a device comprising a tandem cell structure fabricated according to the present invention including a base line cell and an artificial amorphous material cell using crystalline silicon on glass (CSG) technology.

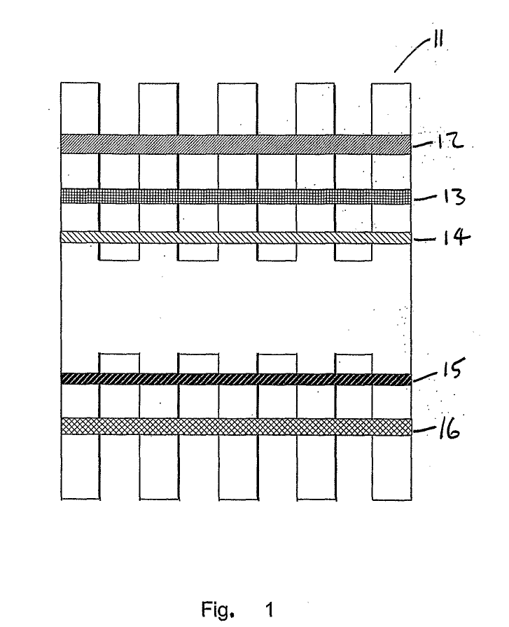

### DETAILED DESCRIPTION OF EMBODIMENTS OF THE INVENTION

A method for forming an artificial amorphous semiconductor material and fabricating a thin-film tandem solar cell using artificial amorphous semiconductor material will now be described in detail. The advantage is that a variable bandgap can be obtained within the same materials system and this materials system is consistent with the exceptional stability and durability of silicon wafer-based product as well as that based on crystalline silicon films on glass. The following examples use silicon as the base semiconductor material however the invention is applicable to other semiconductor materials such as germanium, gallium arsenide or Indium phosphide.

### General Preparation Approach

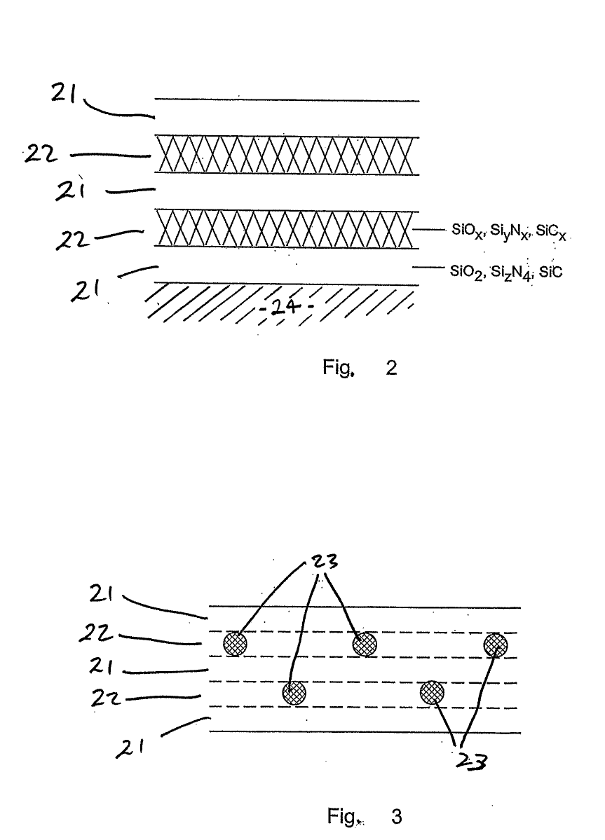

Referring to FIG. 2, to prepare the artificial amorphous material of interest, alternating layers of stoichiometric silicon oxide, nitride or carbide 21 are interspersed with layers of silicon-rich material 22 of the same type. These layers are formed on a substrate 24 which may be glass, ceramic or other suitable material depending on the particular application. On heating, crystallisation of the excess silicon occurs in the silicon-rich layers. As illustrated in FIG. 3, in order to minimise their free energy, the crystallised regions 23 are approximately spherical of a radius determined by the width of the silicon-rich layer, and approximately uniformly dispersed within this layer. If the interspersed layers of stoichiometric material 21 are sufficiently thin, free energy minimisation encourages a symmetric arrangement of quantum dots 23 on neighbouring planes (either in a close-packed arrangement as shown or in related symmetrical configurations) of the dielectric material whereby they are uniformly distributed and regularly spaced in three dimensions through the dielectric material.

Suitable deposition approaches for the layers 21, 22 include physical deposition such as sputtering or evaporation, including these in a reactive ambient, chemical vapour deposition including plasma enhanced processes, or any other suitable processes for depositing the materials involved. Suitable heating processes include heating in a suitable furnace, including belt or stepper furnaces, or heating by rapid thermal processes including lamp or laser illumination amongst others. For approaches resulting in hydrogen incorporation into the layers during deposition, several stages of heating may be required to allow the hydrogen to evolve prior to exposure to the higher crystallisation temperatures

Doping of the quantum dots 23 is achieved by incorporating standard silicon dopants during deposition of either type of layer 21, 22. Some of these are incorporated into nearby quantum dots 23, donating or accepting electrons from neighbouring atoms and imparting donor or acceptor properties. Alternatively, regarding dots 23 as artificial atoms, dots that differ chemically from neighbours, such as by the incorporation of Ge, also can give similar donor or acceptor properties. Dopants can also be incorporated into the matrix or diffused into the dots through the matrix after the dots have been formed.

### Matrix Properties

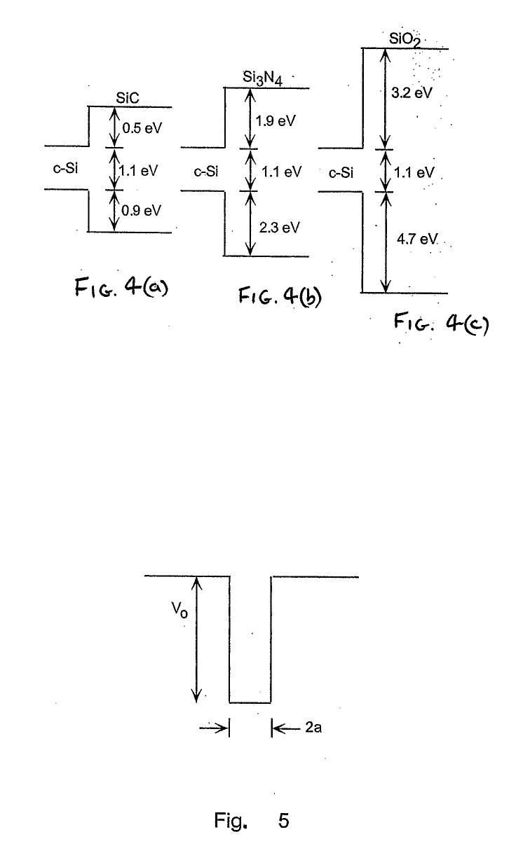

From a materials viewpoint, amorphous silicon carbide, nitride or oxide are ideal matrices to embed the quantum dots 23. Bulk band alignments for silicon carbide (SiC), silicon nitride (Si₃N₄) and silicon oxide (SiO₂) are shown in FIGS. 4(a), 4(b) and 4(c) respectively.

If all dots 23 were the same size, they would act like identical atoms. If close enough to interact, atomic-like levels would broaden out into bands. Those due to confinement within the valence band of the quantum dots would be nearly full, while those due to confinement in the conduction band would be nearly empty. This gives rise to an amorphous-type semiconductor material, since the quantum dots do not have perfect periodicity in all three spatial dimensions.

The bandwidths of the highest valence band and lowest conduction band and the energy of the corresponding band edges, apart from depending on the dot size, would depend on the distance to nearest neighbours, and hence would fluctuate with position, due to non-perfect periodicity of the quantum dot co-ordinates. The effective mobility would depend on the dot spacing. The dots would have to be sufficiently close to allow tunneling between them of current densities typical of the application. For photovoltaic application, relatively large bandwidth would be required to allow a broad spectral response. Overlapping bands, particularly in the valence band, contribute to increased bandwidth.

In the simplest theory, the important parameter in determining the degree of interaction between quantum dots is m*ΔEd², where m* is the bulk effective mass in the respective band of the matrix, ΔE is the energy difference between this bulk band and the band formed by quantum dot interaction and d is the spacing between dots. Due to the different values of ΔE apparent in FIGS. 4(a), (b) and 4(c), the spacing of dots has to be closest in the oxide, followed by the nitride and carbide, in that order.

### Bandgap Control

Referring to FIG. 5 the simplest “effective mass” solutions for electrons confined in a quantum dot 23 are very similar to those for the simple case of a 1D quantum well. For the zero angular momentum case, they are given by:

Eₙ=η²k²/2m* (1)

where k is the solution to the implicit equation:

$$ka = n π - arc sin ( η k / \sqrt{2 {m}^{*} {V}_{o}} ) \qquad ( 2 )$$

where a is the dot radius, m* is the effective mass in the appropriate band of silicon and Vₒ is the corresponding band offset. If this approaches infinity, the solutions become:

$${E}_{n} = \frac{{π}^{2} {η}^{2}}{2 {m}^{*} {a}^{2}} {n}^{2} \qquad ( 3 )$$

This is an identical solution to that for the corresponding 1D well case, although a in this case is the well width. Hence, the confinement energy in a 2 nm diameter dot will be the same as in a 1 nm wide quantum well. Previous measurements demonstrate sufficient confinement in a well of such a 1 nm width for 1.7 eV bandgap. The above theory shows that such a bandgap can be obtained in a silicon quantum dot of about 2 nm diameter, although dots of this size are difficult to measure accurately. This is the ideal bandgap for a 2-cell tandem on bulk silicon. A 1.4 nm diameter quantum dot would, on the same basis, give 2.3 eV bandgap, high enough for the top cell in a 5-cell tandem, again on bulk silicon.

Using the expression:

arcsin x=x+x³/6+ . . . (x²≦1) (4)

gives:

$${E}_{n} \approx \frac{{π}^{2} {η}^{2}}{2 {m}^{*} {a}^{2}} {n}^{2} / {[ 1 + η / ( a \sqrt{2 {m}^{*} {V}_{o}} ) ]}^{2} \qquad ( 5 )$$

but is always less than this quantity. Hence, small confinement barriers will reduce the confinement energy (restricted to Vₒ by the constraint on Eq. (4)).

### Bandwidth and Mobility

The solution for the wavefunction outside the quantum dot in the zero angular momentum case is

$$Ψ ( r , θ , φ ) = \frac{B}{r} exp ( - K r ) \qquad ( 6 )$$

where K is given by:

Eₙ=V₀−η²K²/2m** (7)

where m** is the effective mass in the barrier region. This describes the intercommunication between dots. Attenuation in the case of quantum dots will be slightly more rapid than between 1D wells due to the 1/r term. Since quantum dot spacing similar to radius is likely, this additional attenuation will not be particularly severe.

It is possible to estimate bandwidth and mobilities using the “tight banding approximation”. In a bulk semiconductor, according to the Bloch theorem, an electronic state can be described by the product of a plane wave and a function periodic in the lattice potential. Analogously, in a regular quantum dot array, a state in the nth mini-band can be described by linear combinations of wavefunctions periodic in the quantum dot spacing multiplied by a plane wave. If interactions with adjacent dots are the only ones that are significant, the problem simplifies drastically since the periodic wavefunctions mentioned above can be taken as those of the isolated dot. For the case of ID wells, the dispersion relation E(k_{z}) for motion along the well axis becomes:

Eₙ^{SL}(k_{z})=Eₙ+Sₙ+2Tₙ cos(k_{z}d) (8)

where the shift integral, Sₙ, measures the penetration of the wavefunction of one well into that of neighbouring wells:

$${S}_{n} = {\sum }_{m \neq 0} \int {Ψ}_{n} ( z ) {V}_{o} ( z - md ) {Ψ}_{n} ( z ) d z \qquad ( 9 )$$

while the transfer integral, Tₙ, measures the overlap of the wavefunction of the central well with that of a neighbouring well:

Tₙ=∫Ψₙ(z)Vₒ(z)Ψₙ(z−d)dz (10)

A similar formulation can be developed for quantum dots, although details will change to capture the extra complexity of the 3D geometry.

For the 1D case of quantum wells, it follows from Eq. (8) that the width of the band Δₙ=4Tₙ and that acceleration under an electric field, ξ, equals:

a(t)=(2Td²/η²)cos(k_{z}d)qξ (11)

Including a scattering time, τ, the drift mobility equals:

$${υ}_{D} = {\int }_{t = 0}^{∞} {e}^{- t / τ} a ( t ) d t = \frac{q ξ τ ( 2 {Td}^{ 2} / {η}^{2} )}{1 + {( q ξ τ d / η )}^{2}} \qquad ( 12 )$$

Carrier mobility equals υ_{D}/ξ and therefore depends largely on the scattering time, τ, and the transfer integral, T, or equivalently the bandwidth, Δ. For a reasonable mobility, it is required that the quantity (η²/2Td²), the effective mass within the superlattice, to be not too much larger than the electron rest mass, or T not much smaller than 10⁻²⁰ Joules (60 meV) corresponding to bandwidths, Δ not too much less than 240 meV, for d=1 nm.
Given that:

∫|Ψₙ(z)|²=dz=1 (13)

it can be seen from Eq. (10) that T will be a reasonable fraction of Vₒ only if wave functions have reasonable values at adjacent quantum dot sites. As a rule of thumb, the wavefunction in oxide for electrons near the silicon band edge decreases by a factor of 10 for every 0.4 nm of oxide. Hence, 1 nm oxide is calculated to give a bandwidth of about 12 meV, which gives reasonable mobilities. Nitride or carbide give better results due to their lower barrier heights. These calculations are overly conservative due to resonance-type effects that occur between neighbouring dots.

Such narrow bandwidths pose a problem for absorption over a wide spectral range. However, in actual devices, the valence band situation is very confused with overlapping bands due to light and heavy holes. Other bands will arise for values of angular momentum parameter l≠0. The less than perfect periodicity in the location of the quantum dots also causes band broadening.

A carbide matrix is ideal in this respect as, if the quantum dots are small, the band edge in the quantum dot region is pushed up close to the continuum level in the carbide. Carriers can be generated over a wide bandwidth by excitation between these continuum levels and collected at nearby quantum dots. Tunnelling transport between dots takes place in parallel with the normal conduction processes in the carbide.

### Solar Cell Application

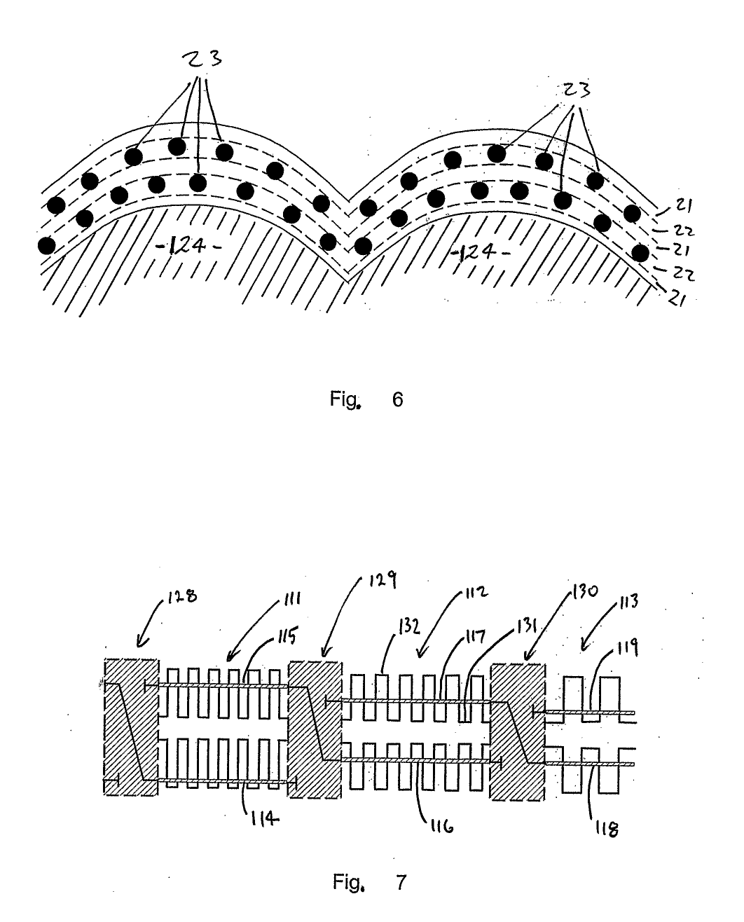

Since the required dimensions of each layer deposited during the formation of the artificial quantum dot material is small (FIG. 2), much smaller than the wavelength of light in such materials, it follows that the textures normally used in solar cells are on a much larger scale than the spacing of the quantum dots. Referring to FIG. 6 a quantum dot structure 21, 22, 23 similar to that seen in FIG. 3 is shown formed on a textured surface of a glass substrate 124. The local ordered arrangement of the dots 23 will determine the superlattice properties regardless of the roughness of the surface at optical wavelengths.

It has been determined experimentally that the strength of the optical emission processes in related quantum well structures increases as the quantum wells become thinner. This is not unexpected since the quantum-mechanical rules that make these processes weak in bulk materials are relaxed in quantum confined geometries.

For silicon-on-glass technology, crystalline layers of 1.6 micron thickness are reported to give good results. The increase in optical strength by confinement depends on experimental details but is of the order of a factor of 10. Hence, required total thickness of the quantum dot artificial semiconductor material will be sub-micron, comparable to the optical wavelength in the material. This allows these layers to double as antireflection layers, due to a lower “effective-medium” refractive index, and to be used in designs which allow a high intensity standing wave to be established in this material, further boosting the absorption properties of the layer.

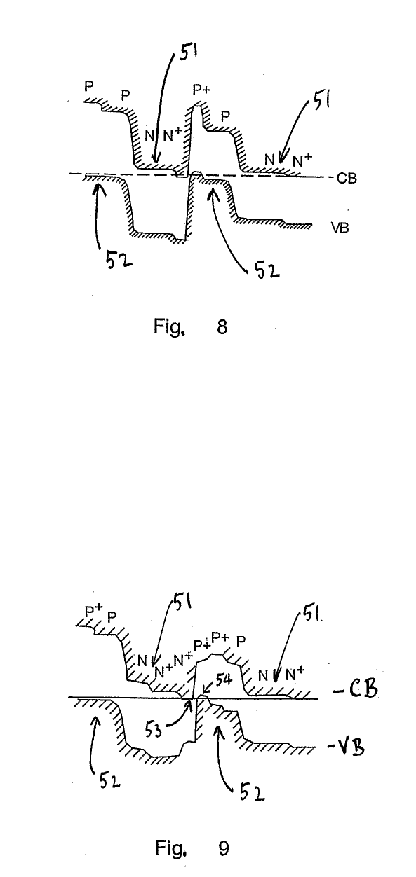

FIG. 7 shows a band structure for a generic tandem solar cell configuration where two artificial amorphous semiconductor cells 111, 112 are illustrated stacked on top of a third artificial amorphous cell 113. The artificial amorphous semiconductor cells 111, 112, 113 are quantum dot superlattices fabricated as described herein. In FIG. 7 the dot width is represented by the width of the lows 131 in the upper square wave, and the matrix width (dot spacing) is represented by the high edges 132 in the upper square wave. The effective bandgap is represented as the gap between the minibands in the valance bands 114, 116,118 and the respective conduction bands 115, 117, 119 and increases with increasing quantum confinement (decreasing dot width). Interconnection regions 128, 129, 130 between adjacent cells (the connection of the valance bands 116,118 of one cell to the conduction band 115, 117 of the next) are formed using either a heavily doped tunneling junction or a highly defected junction. The approach allows any desired number of cells to be stacked on top of one another, with a consequent increase in efficiency potential, but with a greater sensitivity in performance to spectral content of the illuminating light.

These cells could be readily incorporated into “silicon-on-glass” technology which has been developed to exploit thin film solar cells using conventional polycrystalline silicon material. With reference to FIG. 10, after deposition of the barrier layer 25 (eg a thin silicon nitride layer) onto a textured glass superstrate 24, a layer of one polarity of the artificial quantum dot material 26 (i.e. a superlattice of layers doped with one polarity dopant—eg an n⁺ type layer) is deposited using the approach described with reference to FIG. 2, followed by a layer of the opposite polarity 27 (eg a p type layer). Each of these quantum dot layers will preferably comprise in the order of 25 layer pairs (i.e. a pair of one stoichiometric layer and one semiconductor rich layer) with each layer pair being in the order of 4 nm thick (i.e. 2 nm per individual dielectric layer). Each of the artificial quantum dot material layers 26, 27 and 28 are deposited as amorphous stoichiometric or silicon rich dielectric layers by a process such as Plasma Enhanced Chemical Vapour Deposition (PECVD) or an other suitable deposition process. The heating step to form quantum dots may occur immediately or after subsequent processing. This is then followed by the cell interconnection layer 28, discussed below, and then either another artificial amorphous material cell or the baseline silicon device.

For simplicity we will describe an embodiment in which the cell behind the first artificial amorphous material cell is a base line silicon cell. In this case, an n⁺-type silicon layer 29 is deposited over the p⁺-type interconnection layer 28. A p-type silicon layer 31 is then deposited over the n⁺-type silicon layer 29 and a p⁺-type silicon layer 32 is deposited over p-type silicon layer 31. Each of the silicon layers 29, 31 and 32 are deposited as amorphous silicon layers by a process such as Plasma Enhanced Chemical Vapour Deposition (PECVD) or another suitable deposition process. The silicon layers can then be crystallised by solid phase crystallisation, possibly during a thermal anneal step. The step of crystallising the amorphous silicon may also be used to crystallise the quantum dots in the artificial amorphous material if the temperature of the preceding process steps has not already caused this to happen. Alternatively the step of crystallising the quantum dots in the artificial amorphous material may be completed as part of a further Rapid Thermal Anneal step towards the end of the processing sequence.

Before contacts are formed on the device, it is scribed to create isolation grooves 39 to separate the individual cells, and a dielectric layer 33 is added (such as a layer of organic resin). Craters 34 and dimples 35 are then created to expose the front layer 26 and the back layer 32 respectively and a metal layer is formed over the dielectric and extending into the craters and dimples to contact the front layer 26 and rear layer 32. Finally the metal is scribed to form isolation grooves 41, 42 between n-type and p-type contacts while links 43 are left in place to provide series connections between adjacent cells.

If a single artificial quantum dot cell is used on top of a silicon baseline device of 1.1 eV bandgap, the optimum bandgap of the quantum dot material is 1.7 eV. If this cell is of the same material quality as the baseline device, a 25-30% increase in performance over that of the baseline device can be obtained. If two quantum dot cells are added on top of the baseline device, their optimum bandgaps are 2.0 and 1.5 eV, with performance boosted by 35-40%.

There are diminishing returns for adding more cells. For three cells added to give a four-cell tandem the gain over a single device increases to 40-45% (bandgaps of 2.2, 1.7, 1.4 and 1.1 eV), increasing to 45-50% for a 5-cell tandem (bandgaps of 2.3, 1.9, 1.6, 1.3 and 1.1 eV), but is still less than 50% for a 6-cell tandem (bandgaps of 2.4, 2.0, 1.7, 1.5, 1.3 and 1.1 eV). Decreasing the bandgap of the baseline device by alloying with germanium is one way of further improving performance.

The design of the interconnections between the cells requires special consideration. In bulk crystalline devices, these interconnections are normally achieved by tunneling junctions for which an energy diagram is shown in FIG. 8. Electrons in the conduction band 51 of the n⁺-type semiconductor material can tunnel through the junction to the valence band 52 of opposite polarity (i.e. p⁺-type) material, if both regions are heavily doped. Alternatively, badly shunted, low-quality junctions, as will often occur when both sides are heavily doped or when defects are deliberately added to this region, can achieve the same effect. Physically, both have the same effect in that the relevant interface acts as a high recombination velocity surface, which can detract from cell performance.

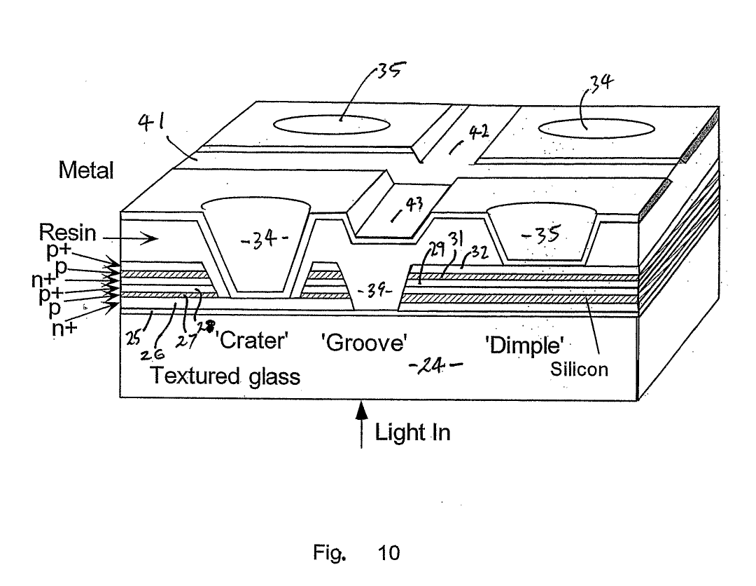

Various methods can be used to isolate such regions. The most effective is to use smaller, heavily doped quantum dots in this area, that increases the effective bandgap in this region. This would decrease the amount of light absorbed in this region, as in the design of crystalline tandem cells (refer again to FIG. 8). However, referring to FIG. 9, very thin but highly doped layers of the baseline n⁺ material 53 and p⁺ material 54 can also be used in this region. Although not having the previous advantages, this produces advantages in terms of reduced lateral resistance of the device due to the higher mobility of carriers in such layers.

FIG. 10 and the associated description show one method of partitioning the material, initially deposited over the entire substrate or superstrate area, into individual cells and then interconnecting these. Variants of other well-established methods are also suitable.

### Inverse Tandem Cells

Due to the excellent light-trapping demonstrated by silicon-on-glass and related baseline technologies, novel tandem cell configurations become possible. For example, if sufficiently thin, it is possible to place the low bandgap cell on top of the high-bandgap cell, while still retaining a reasonable fraction of the performance gain. For example, a circa-1.6 eV cell placed behind a baseline cell of 1.0-1.5 micron thickness could still boost performance by 20%.

Particularly advantageous, in terms of contacting, could be cells where baseline materials are used both at the top and bottom of a stack. The simplest 3-cell stack of this type would have the 1.1 eV baseline top cell of sub-micron thickness, followed by a circa-1.8 eV bandgap device, followed by a second 1.1 eV sub-micron device and again give a 20% boost, assuming all cells are of a similar quality.

The required cell thicknesses and bandgaps are a sensitive function of the quality of the light-trapping scheme and are determined by detailed experimentation.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1-15. (canceled)

16. A method of forming an artificial amorphous semiconductor material having a controlled bandgap and mobility comprising;
forming a plurality of layers of dielectric material comprising a compound of a semiconducting material, wherein alternating layers are layers of stoichiometric dielectric material and layers of semiconductor rich dielectric material respectively, and
heating the layers of dielectric material to cause quantum dots to form in the semiconductor rich layers of dielectric material whereby they are substantially uniformly distributed and substantially regularly spaced in three dimensions through the dielectric material,
wherein the bandgap and mobility are determined by selecting the material parameters including the size of the quantum dots, the composition of the matrix and the semiconductor material of the quantum dots to achieve the desired parameters.

17. The method of claim 16 wherein the layers of dielectric material are formed in layered regions, the semiconductor rich layers of dielectric material are undoped or are doped to become n-type or p-type material and wherein adjacent regions are differently doped.

18. The method of claim 17 wherein each of the differently doped regions are formed by forming in the range of 20-50 layers of each of the stoichiometric and semiconductor rich material layers.

19-23. (canceled)

24. The method as claimed in claim 16 wherein the semiconductor material of the semiconductor rich material layers is silicon.

25. The method as claimed in claim 16 wherein the semiconductor material of the semiconductor rich material layers is a silicon alloy.

26. The method of claim 25 wherein the semiconductor material of the semiconductor rich material layers is silicon alloyed with germanium.

27. (canceled)

28. The method as claimed in claim 16 wherein the dielectric material is formed in a layered structure the method comprising forming layers of one or more materials selected from silicon oxide, silicon nitride and silicon carbide.

29. The method of claim 28 further comprising forming layers of one or more materials other than silicon oxide, silicon nitride and silicon carbide.

30. A photovoltaic junction comprising an n-type region of artificial amorphous material adjacent a p-type region of artificial amorphous material forming a junction there between, the n-type and p-type artificial amorphous materials being integrally formed as a matrix of dielectric material in which is substantially regularly disbursed a plurality of crystalline semiconductor material quantum dots and wherein the n-type and p-type regions are respectively doped with n-type and p-type dopant atoms.

31. The photovoltaic junction of claim 30 further comprising a region in the vicinity of the junction between the n-type and p-type regions of the artificial amorphous material which is undoped or has a balance of n-type and p-type dopants whereby the region behaves as intrinsic material.

32-44. (canceled)

45. An artificial amorphous material photovoltaic cell comprising a plurality of photovoltaic junctions as claimed in claim 30 stacked in tandem.

46. An artificial amorphous material photovoltaic cell comprising a crystalline semiconductor material junction and a photovoltaic junction as claimed in claim 30 stacked in tandem.

47. The artificial amorphous material photovoltaic cell as claimed in claim 44 wherein the crystalline semiconductor junction is a poly crystalline silicon junction.

48. The artificial amorphous material photovoltaic cell as claimed in claim 45 or 47 wherein the bandgaps of the stacked junctions vary from junction to junction within the cell.

49. A method of forming an artificial amorphous semiconductor material photo voltaic cell comprising;
forming a plurality of layers of dielectric material comprising a compound of a semiconducting material, wherein alternating layers are layers of stoichiometric dielectric material and layers of semiconductor rich dielectric material respectively,
doping regions of the plurality of layers of dielectric material with p-type and n-type dopants either simultaneously with their formation or subsequently, and
heating the layers of dielectric material to cause quantum dots to form in the semiconductor rich layers,
wherein the bandgap and mobility are determined by selecting the material parameters including the size of the quantum dots, the composition of the matrix and the semiconductor material of the quantum dots to achieve the desired parameters.

50. The method of claim 49 further comprising forming a region between the n-type and p-type regions of the artificial amorphous material which is undoped or has a balance of n-type and p-type dopants whereby the region behaves as intrinsic material.

51-56. (canceled)

57. The method as claimed in claim 49 wherein the semiconductor material of the semiconductor rich material layers is silicon.

58. The method as claimed in claim 49 wherein the semiconductor material of the semiconductor rich material layers is a silicon alloy.

59. The method of claim 58 wherein the semiconductor material of the semiconductor rich material layers is silicon alloyed with germanium.

60-62. (canceled)

63. The method as claimed in claim 49 comprising forming a plurality of alternating p and n type regions to form a plurality of photovoltaic junctions stacked in tandem.

64. The method as claimed in claim 49 further comprising forming a crystalline semiconductor material junction in stacked tandem with the artificial amorphous material photovoltaic cell.

65. The method of claim 64 wherein the crystalline semiconductor junction is a poly crystalline silicon junction.

66. The method as claimed in claim 63 wherein the bandgaps of the stacked junctions are selected to vary from junction to junction within the cell.

67. An artificial amorphous semiconductor material having a controlled bandgap and mobility comprising a plurality of crystalline semiconductor material quantum dots substantially uniformly distributed and regularly spaced in three dimensions through a matrix of dielectric material or thin layers of dielectric materials wherein the bandgap and mobility of the material are determined by selecting the material parameters including the size of the quantum dots, the composition of the matrix and the semiconductor material of the quantum dots.

68. The artificial amorphous semiconductor material of claim 67 wherein the quantum dots are distributed in layers throughout the artificial amorphous material.

69. The artificial amorphous semiconductor material of claim 67 wherein the quantum dots are located in layered regions with quantum dots in adjacent regions being differently doped.

70. The artificial amorphous semiconductor material as claimed in claim 67 wherein the semiconductor material of the quantum dots is silicon.

71. The artificial amorphous semiconductor material as claimed in claim 67 wherein the semiconductor material of the quantum dots is a silicon alloy.
